(19) United States
(12) Patent Application Publication
(10) Pub. No.: US 2019/0257482 A1
(43) Pub. Date: Aug. 22, 2019

(54) LIGHT-EMITTING APPARATUS

(71) Applicant: PANASONIC INTELLECTUAL PROPERTY MANAGEMENT CO., LTD., Osaka (JP)

(72) Inventors: Masumi ABE, Osaka (JP); Toshiaki KURACHI, Kyoto (JP)

(73) Assignee: PANASONIC INTELLECTUAL PROPERTY MANAGEMENT CO., LTD., Osaka (JP)

(21) Appl. No.: 16/253,982

(22) Filed: Jan. 22, 2019

(30) Foreign Application Priority Data
Feb. 22, 2018 (JP) 2018-029750

(51) Int. Cl. F21K 9/64; F21K 9/20; H01L 33/56; H01L 33/50; H01L 33/62

(52) U.S. Cl. CPC F21K 9/64; F21K 9/20; F21Y 2115/10; H01L 33/504; H01L 33/62; H01L 33/56

(57) ABSTRACT

A light-emitting apparatus includes: a base; a wiring pattern disposed on a major surface of the base; a light-emitting element mounted on the major surface of the base; a metal wire that electrically connects the light-emitting element and the wiring pattern; a light-transmissive film that covers the metal wire, at least a portion of the wiring pattern, and at least a portion of the light-emitting element; and a sealant that covers the light-transmissive film. The light-transmissive film includes a wall portion that is located between the metal wire and the base, and that extends from the major surface of the base to the metal wire.

### CROSS REFERENCE TO RELATED APPLICATION

This application claims the benefit of priority of Japanese Patent Application Number 2018-029750 filed on Feb. 22, 2018, the entire content of which is hereby incorporated by reference.

### BACKGROUND

### 1. Technical Field

The present disclosure relates to a light-emitting apparatus having configuration in which light-emitting elements are disposed on a base.

### 2. Description of the Related Art

Light-emitting elements, such as light-emitting diodes (LEDs), are widely utilized as highly efficient and space-saving light sources in various light-emitting apparatuses for lighting applications or display applications, for example. Japanese Unexamined Patent Application Publication No. 2014-158052 discloses a light-emitting apparatus that carries LEDs disposed on the substrate and sealed by a sealant.

### SUMMARY

A light-emitting apparatus gives off heat when light-emitting elements emit light, in other words, the light-emitting apparatus is turned on. At that time, a sealant at seals the light-emitting elements expands or contracts due to the heat, and thus deforms. When the light-emitting apparatus is repeatedly turned on and off, the sealant is repeatedly exposed to the heat from the light-emitting elements, and repeatedly deforms by expanding and contracting. At this time, a metal wire connected to the light-emitting element to supply the electric power is repeatedly exposed to the stress caused by the deformation of the sealant. The metal wire repeatedly exposed to such a stress may be at increased risk of breakage. Thus, the light-emitting apparatus needs to be resistant to failure even when the light-emitting apparatus is repeatedly exposed to heat. In other words, the light-emitting apparatus needs to have heat cycle resistance.

The present disclosure provides a light-emitting apparatus having improved heat cycle resistance.

A light-emitting apparatus according to one aspect of the present disclosure includes: a base; a wiring pattern disposed on a major surface of the base; a light-emitting element mounted on the major surface of the base; a metal wire that electrically connects the light-emitting element and the wiring pattern; a light-transmissive film that covers the metal wire, at least a portion of the wiring pattern, and at least a portion of the light-emitting element; and a sealant that covers the light-transmissive film. The light-transmissive film includes a wall portion that is located between the metal wire and the base, and that extends from the major surface of the base to the metal wire.

The light-emitting apparatus according to one aspect of the present disclosure achieves improved heat cycle resistance.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is an external perspective view of a light-emitting apparatus according to Embodiment 1;

FIG. 2 is a cross-sectional view taken along line II-II in FIG. 1;

FIG. 3 is an enlarged view of an upper surface part for illustrating a light-transmissive film included in the light-emitting apparatus according to Embodiment 1;

FIG. 4 is a cross-sectional view taken along line IV-IV in FIG. 3;

FIG. 5A is a table for illustrating a configuration of a light-emitting apparatus according to a working example and a configuration of a light-emitting apparatus according to a comparative example;

FIG. 5B is a table showing the result of a heat cycle test performed on the light-emitting apparatus according to the working example and the light-emitting apparatus according to the comparative example; and

FIG. 6 is a cross-sectional view of a light-emitting apparatus according to Embodiment 2.

### DETAILED DESCRIPTION OF THE EMBODIMENTS

The light-emitting apparatuses according to embodiments will be described with reference to the drawings. Each of the embodiments described below is a general or specific example. The numerical values, shapes, materials, structural components, arrangement and connection of the structural components, steps, and order of the steps, etc., indicated in the following embodiments are given merely by way of illustration and are not intended to limit the present disclosure. Among structural components in the following embodiments, those not recited in any one of the independent claims defining the broadest inventive concept of the present disclosure are described as optional structural components.

Note that the figures are schematic illustrations and are not necessarily precise depictions. Moreover, in the figures, structural components that are essentially the same share like reference signs. Accordingly, duplicate description may be omitted or simplified.

Moreover, in the detailed description and drawings, the X, Y, and Z axes indicate the three axes in a three-dimensional orthogonal coordinate system. The X and Y axes are orthogonal to one another and the Z axis. In the following embodiments, the positive direction in the Z axis may be described as above, and the negative direction in the Z axis may be described as below.

### Embodiment 1

### [Configuration]

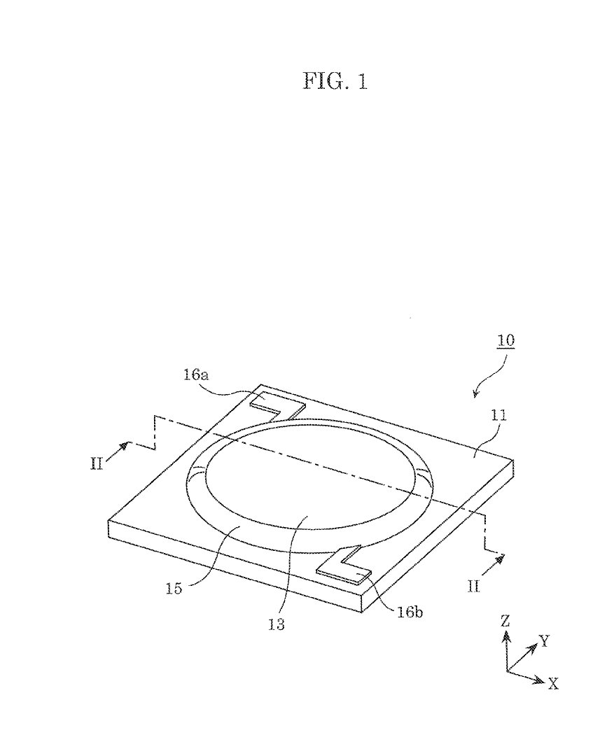

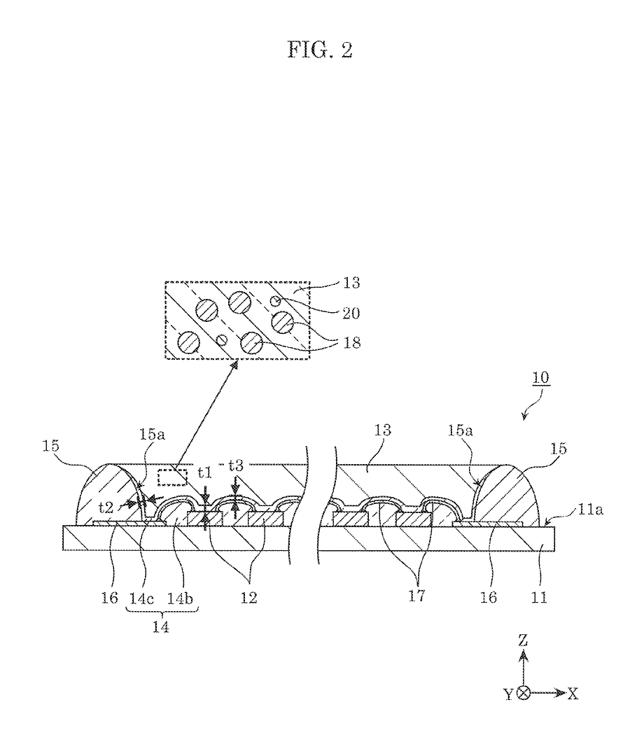

First, the configuration of light-emitting apparatus 10 according to Embodiment 1 will be described with reference to 1 to 4. FIG. 1 is an external perspective view of light-emitting apparatus 10 according to Embodiment 1. FIG. 2 is a cross-sectional view taken along line II-II in FIG. 1.

As illustrated in FIG. 2, light-emitting apparatus 10 is an LED module having a so-called chip-on-board (COB) structure, in which a plurality of light-emitting elements 12 are directly disposed (i.e., mounted) on major surface 11a of base 11.

As illustrated in FIGS. 1 and 2, light-emitting apparatus 10 includes: base 11; light-emitting elements 12; sealant 13; light-transmissive film 14; frame 15; wiring patterns 16; electrodes 16a and 16b; and metal wires 17. Wiring patterns 16 are electrically connected to respective electrode 16a and electrode 16b. Electrodes 16a, and 16b are connected to an external commercial power source, etc., which is not illustrated. Light-emitting apparatus 10 emits light with electric power supplied from the external commercial power source, etc.

Base 11 is a member having a plate-like shape and having major surface 11a. Specifically, base 11 is a plate material on which a plurality of light-emitting elements 12 are disposed on major surface 11a. Base 11 is, for example, a metal-based substrate that includes a metal material or a ceramic substrate that includes ceramic. Moreover, base 11 may be a resin substrate that includes a resin.

As the ceramic substrate, an alumina substrate that includes aluminum oxide (alumina), or an aluminum nitride substrate that includes aluminum nitride, for instance, is employed. As the metal-based substrate, an aluminum alloy substrate, an iron alloy substrate, or a copper alloy substrate that has a surface on which an insulating film is formed is employed, for example. As the resin substrate, a glass epoxy substrate that includes glass fiber and an epoxy resin is employed, for example.

Note that for example, a substrate having a high light reflectance (a light reflectance of 90% or higher, for example) may be employed as base 11. By employing a substrate having a high light reflectance as base 11, light emitted by light-emitting elements 12 can be reflected off the surface of base 11. As a result, the light extraction efficiency of light-emitting apparatus 10 improves. An example of such a substrate is a white ceramic substrate whose base material is alumina.

A light-transmitting substrate having a high light transmittance may be employed as base 11. Examples of such a substrate include a light-transmitting ceramic substrate that includes polycrystalline alumina or aluminum nitride, etc., a transparent glass substrate that includes glass, a crystal substrate that includes crystal, a sapphire substrate that includes sapphire, and a transparent resin substrate that includes a transparent resin material. Note that base 11 illustrated in FIG. 1 has a quadrilateral shape in a plan view, but may have a shape other than the quadrilateral shape, such as a round shape.

Light-emitting elements 12 are light sources of light-emitting apparatus 10, and emit fight. Light-emitting elements 12 are, for example, blue LED chips that emit blue light. For example, gallium nitride LED chips formed from an InGaN-based material and having a center wavelength (peak wavelength of an emission spectrum) of at least 430 nm and at most 480 nm, are employed as light-emitting elements 12.

A plurality of light-emitting element lines including two or more light-emitting elements 12 are provided on base 11. Moreover, light-emitting elements 12 are connected to one another in series in a chip-to-chip configuration mainly by metal wires 17.

Metal wires 17 are bonding wires that supply, to light-emitting elements 12, electric power supplied from a power source such as an external commercial power source via electrodes 16a and 16b, and wiring patterns 16. The external commercial power source is not illustrated in the drawings. Alternatively, metal wires 17 are bonding wires that electrically connect light-emitting elements 12 to one another. Metal wires 17 may include gold, for example. However, metal wires 17 may include metal other than gold, such as silver and copper. Note that light-emitting apparatus 10 may include at least one light-emitting element 12.

Wiring patterns 16 are metal wiring patterns formed on major surface 11a of base 11. Light-emitting apparatus 10 is partially covered with frame 15. Wiring patterns 16 are electrically connected to electrodes 16a and 16b. Specifically, portions of wiring patterns 16 are electrodes 16a and 16b that are not covered with frame 15 and sealant 13, and connected to the external commercial power source, which is not illustrated. Wiring patterns 16 are electrically connected to light-emitting elements 12 via metal wires 17. In other words, electrodes 16a and 16b are electrically connected to light-emitting elements 12 via wiring patterns 16 and metal wires 17. Wiring patterns 16, and electrodes 16a and 16b include gold, for example, but may include metal other than gold, such as silver and copper.

Sealant 13 is a sealing member that seals a plurality of light-emitting elements 12, light-transmissive film 14, metal wires 17, and portions of wiring patterns 16. In the plan view, sealant 13 is formed in a circular shape by being dammed up by frame 15 having a circular ring shape. Note that the plan view refers to a view of light-emitting apparatus 10 from a direction perpendicular to major surface 11a of substrate 11.

Sealant 13 includes, for example, phosphor 18 (phosphor particles) that converts the wavelengths of light emitted by light-emitting elements 12. Specifically, light-emitting apparatus 10 may include phosphor 18 that is sealed by sealant 13 and emits fluorescence. The light emitted by light-emitting elements 12 includes excitation light for phosphor 18. As sealant 13, a silicone resin is used, for example, but sealant 13 may be an epoxy resin or a urea resin, for example. For example, yttrium aluminum garnet (YAG)-based yellow phosphor particles are employed as phosphor 18.

With this configuration, a portion of blue light emitted by blue LED chips, which are one example of light-emitting elements 12, is wavelength-converted into yellow light by yellow phosphor particles included in sealant 13. The yellow phosphor particles are one example of phosphor 18. Then, the blue light not absorbed in the yellow phosphor particles and the yellow light obtained by the wavelength-conversion by the yellow phosphor particles are diffused and mixed in sealant 13. As a result of mixing the blue light not absorbed in the yellow phosphor particles and the yellow light obtained by the wavelength conversion by the yellow phosphor particles, white light is emitted from sealant 13 as mixed light. Note that sealant 13 also serves to protect light-emitting elements 12 and metal wires 17 from refuse, moisture, external force, etc.

Inorganic filler 20 may be included in sealant 13. Inorganic filler 20 is a member that reduces settling of phosphor 18. The material of inorganic filler 20 is silica having a particle diameter of approximately 10 nm, for example. However, a material other than silica may be used.

Sealant 13 may include at least 10 ppm of cerium (Ce). A non-limiting example of Ce to be added to sealant 13 includes a Ce complex.

Frame 15 is a member that surrounds light-emitting elements 12 in a top view to dam up sealant 13 before sealant 13 is cured. In other words, frame 15 is a dam member and is adjacent to sealant 13.

For example, a thermosetting resin or a thermoplastic resin having insulating properties is used as frame 15. More specific examples of frame 15 include a silicone resin, a phenol resin, an epoxy resin, a bismaleimide triazine resin, and a polyphthalamide (PPA) resin.

Note that frame 15 may have light-reflecting properties in order to increase the light extraction efficiency of light-emitting apparatus 10. For example, a white resin including a white pigment, etc. may be used as frame 15. In order to increase the light reflection properties of frame 15, TiO₂ particles, Al₂O₃ particles, ZrO₂ particles, or MgO particles, for instance, may be included in frame 15. Note that the material of frame 15 is not limited to a resin, and a material such as ceramic may be used, for example.

In light-emitting apparatus 10, frame 15 is formed in a circular ring shape to surround light-emitting elements 12 in the top view. This improves the light extraction efficiency of light emitting apparatus 10. Note that for example, frame 15 may be formed to have an outline in a quadrilateral ring shape in the top view. It is sufficient that frame 15 has a form that surrounds two or more light-emitting elements 12 in the top view.

Light-transmissive film 14 is a light-transmissive resin material that covers metal wires 17.

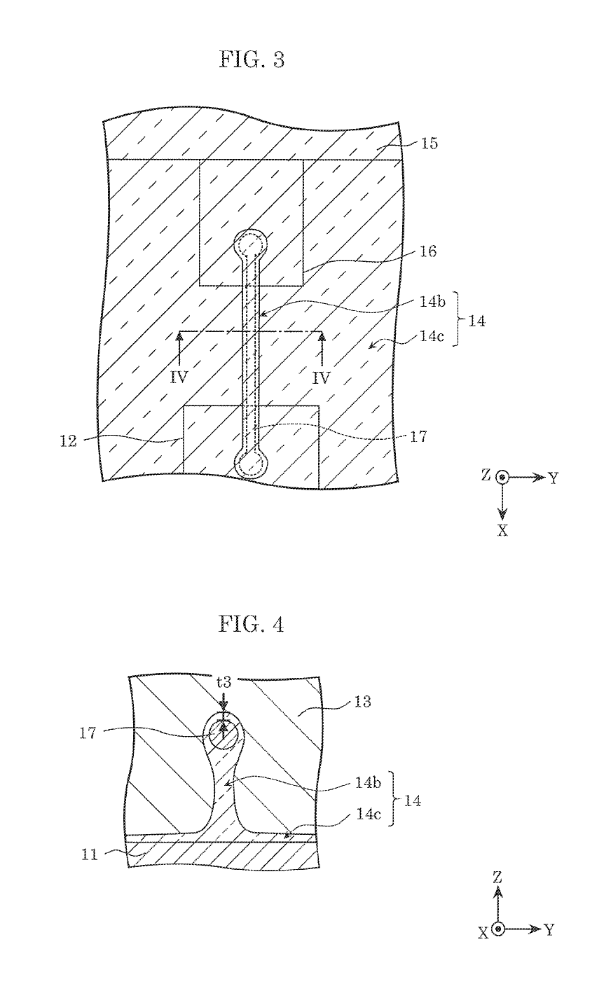

FIG. 3 is an enlarged view of an upper surface part for illustrating light-transmissive film 14 included in light-emitting apparatus 10 according to Embodiment 1. FIG. 4 is a cross-sectional view taken along line IV-IV in FIG. 3. Note that in FIG. 3, sealant 13 is not shown for purposes of illustration.

As illustrated in FIGS. 3 and 4, light-transmissive film 14 is formed to cover each of metal wires 17. Moreover, as illustrated in FIG. 4, light-transmissive film 14 covers, for example, the entire perimeter in the radial direction of metal wire 17. Light-transmissive film 14 includes, as illustrated in FIGS. 2 and 4, wall portion 14b that is located between metal wire 17 and base 11, and extends from major surface 11a of base 11 to metal wire 17. Light-transmissive film 14 also includes layer portion 14c that is a layer covering at least a portion of wiring pattern 16 and at least a portion of light-emitting element 12. Wall portion 14b of light-transmissive film 14 is formed continuously to cover metal wire 17 along the extending direction of metal wire 17 (the X axis direction in FIG. 3), in a top view of major surface 11a of base 11. Light-transmissive film 14 continuously covers metal wire 17, major surface 11a of base 11, wiring pattern 16, and light-emitting element 12.

Wall portion 14b is formed to extend from major surface 11a of base 11 to metal wire 17, and support metal wire 17 from below. In other words, wall portion 14b included in light-transmissive film 14 has a curtain-like form that extends in XZ plane between metal wire 17 and major surface 11a of base 11, and extends the extending direction of metal wire 17 (i.e., the X axis direction). Wall portion 14b is formed continuously along wiring pattern 16 and light-emitting element 12, for example. At least a portion of wall portion 14b is located at a position surrounded by major surface 11a of base 11, light-emitting element 12, wiring pattern 16, and metal wire 17 that electrically connects light-emitting element 12 and wiring pattern 16. For example, when light-emitting apparatus 10 includes two or more light-emitting elements 12, at least a portion of wall portion 14b is located at a position surrounded by major surface 11a of base 11, two light-emitting elements 12, and metal wire 17 that electrically connects the two light-emitting elements 12. For example, the width of wall portion 14b in the direction orthogonal to the extending direction of metal wire 17 (i.e. the width in the Y axis direction) is partially thinner than the diameter of metal wire 17. The extending direction of metal wire 17 is the direction parallel to major surface 11a.

Layer portion 14c continuously covers major surface 11a of base 11, wiring pattern 16, and upper surface and side surface of light-emitting element 12. Light-transmissive film 14 covers a portion of frame 15 as illustrated in FIG. 2. Specifically, coverage by layer portion 14c of light-transmissive film 14 continuously extends from major surface 11a of base 11, wiring pattern 16, etc. to inner surface 15a of frame 15. A thickness of light-transmissive film 14 in a portion that covers light-emitting element 12 may be greater than a thickness of light-transmissive film 14 in a portion that covers frame 15. Specifically, thickness t1 of light-transmissive film 14 in a portion that covers light-emitting element 12 may be greater than thickness t2 of light-transmissive film 14 in a portion that covers frame 15.

Moreover, the thickness of light-transmissive film 14 in a portion that covers metal wire 17 positioned opposite to base 11 in the normal direction of major surface 11a of base 11 may be at most 50 μm. Specifically, as illustrated in FIGS. 2 and 4, thickness t3 of light-transmissive film 14 in a portion that covers each of metal wires 17 in the Z axis direction may be at most 50 μm.

Moreover, the hardness of light-transmissive film 14 may be greater than the hardness of sealant 13. For example, the hardness is indicated using the type A durometer hardness according to JIS K 6253-3. Note that the hardness may be compared with reference to Vickers hardness, etc. For example, as a material of light-transmissive film 14, a material having a higher crosslink density and being more unlikely to expand with heat than the material used as sealant 13 is employed.

Light-transmissive film 14 is formed as follows, for example. On major surface 11a of base 11, light-emitting element 12, frame 15, wiring pattern 16, electrodes 16a and 16b, and metal wire 17 are disposed, and a space defined by base 11 and frame 15 is formed. A solution obtained by diluting, with a liquid diluent, which is a solvent, approximately 5% of a material of light-transmissive film 14 (specifically, a solid material that is a main component of light-transmissive film 14) is poured into the space defined by base 11 and frame 15. The liquid diluent is volatilized and light-transmissive film 14 is obtained. The solvent is not specifically limited and a well-known organic solvent may be used as long as the solvent is an organic solvent and dissolves a solid material, which is a main component of light-transmissive film 14, to provide a uniform solution. Examples of the solvent include: aromatic hydrocarbon solvents such as xylene, toluene, and benzene; aliphatic hydrocarbon solvents such as heptane and hexane; halogenated hydrocarbon solvents such as trichloroethylene, perchloroethylene, and methylene chloride; ester solvents such as ethyl acetate; ketone solvents such as methyl isobutyl ketone, and methyl ethyl ketone; alcohol solvents such as ethanol, isopropanol, and butanol; silicone-based solvents such as ligroin, cyclohexanone, diethyl ether, and rubber solvent. Note that light-transmissive film 14 may be formed at a desired position such as around metal wire 17, etc. using a dispenser, for example.

Light-transmissive film 14 is formed from, for example, a glass material (specifically, a so-called glass-like material). Alternatively, the material of light-transmissive film 14 may be a fluorine-based material including fluorine. Instead of the above materials, the material of light-transmissive film 14 may be a nitrogen-based material including nitrogen.

Specifically, light-transmissive film 14 includes, as a main component, one of (i) a homopolymer of SiH group-containing (meth)acrylic ester and (ii) a copolymer of SiH group-containing (meth)acrylic ester and at least one selected from the group consisting of acrylic esters and methacrylic esters. Note that the term “(meth/acrylic ester” includes the terms “acrylic ester” and “methacrylic ester”.

A well-known acrylic ester may be employed as an acrylic ester included in light-transmissive film 14 as a main component. Examples of the acrylic ester include: methyl acrylate, ethyl acrylate, n-butyl acrylate, isobutyl acrylate, isopentyl acrylate, n-hexyl acrylate, isooctyl acrylate, 2-ethylhexyl acrylate, n-octyl acrylate, isononyl acrylate, n-decyl acrylate, and isodecyl acrylate.

A well-known methacrylic ester may be employed as a methacrylic ester included in light-transmissive film 14 as a main component. Examples of methacrylic esters include: methyl methacrylate, ethyl methacrylate, n-butyl methacrylate, isobutyl methacrylate, isopentyl methacrylate, n-hexyl methacrylate, isooctyl methacrylate, 2-ethylhexyl methacrylate, n-octyl methacrylate, isononyl methacrylate, n-decyl methacrylate, and isodecyl methacrylate.

For example, light-transmissive film 14 may include, as a main component, an acrylic resin including at least one of (i) an acrylic ester containing an Si-vinyl group and not containing an SiH group, and (ii) a methacrylic ester containing an Si-vinyl group and not containing an SiH group.

A well-known acrylic resin may be employed as the acrylic resin included in light-transmissive film 14 as a main component. Examples of the acrylic resin include: a homopolymer of acrylic ester containing one or more Si-vinyl groups per molecule; a homopolymer of methacrylic ester containing one or more Si-vinyl groups per molecule; a copolymer of acrylic ester containing one or more Si-vinyl groups per molecule, and a methacrylic ester containing one or more Si-vinyl groups per molecule; a copolymer of acrylic ester containing one or more Si-vinyl groups per molecule and another acrylic ester different from the other acrylic ester; a copolymer of methacrylic ester containing one or more Si-vinyl groups per molecule, and another methacrylic ester different from the other methacrylic ester.

For example, light-transmissive film 14 may include, as a main component, a reaction product of a (poly)silazane-based compound. Note that a (poly)silazane-based compound is a compound containing a silazane compound having one silazane bonding, or a compound containing a polysilazane compound.

A well-known (poly)silazane-based compound may be employed as such a (poly)silazane-based compound. Examples of the (poly)silazane-based compound include: a (poly)silazane-based compound having a R′2Si(NR)2/2 unit and/or a R′Si(NR)3/2 unit (where R represents a hydrogen atom or a monovalent organic group and R′ is a monovalent organic group).

A (poly)silazane-based compound generates hydrogen and ammonia when producing a reaction product. Here, the reaction product is a material generated when light-transmissive film 14 is formed. The reaction product is SiO₂, for example.

Light-transmissive film 14 may include, as a main component, an acrylic resin including at least one of (i) a (poly)silazane-based compound and an SiH group-containing acrylic ester and (ii) an SiH group-containing methacrylic ester.

For example, light-transmissive film 14 includes, as main components, a methacrylic ester, an (meth)acrylic ester, and a fluorine-containing monomer.

A well-known fluorine-containing monomer may be employed as the fluorine-containing monomer included in light-transmissive film 14 as a main component. Examples of the fluorine-containing monomer include: a perfluorobexylethyl (meth)acrylate, and perfluorobutylethyl (meth)acrylate.

Note that light-transmissive film 14 may further include a carboxy-containing monomer as a main component.

A well-known carboxy-containing monomer may be employed as the carboxy-containing monomer included in light-transmissive film 14 as a main component. Examples of the carboxy-containing monomer include: methacrylic acid, 2-methacryloyloxy phthalate, 2-methacryloyloxyethyl succinate, 2-methacryloyloxyethyl hexahydrophthalate, acrylic acid, 2-acryloyloxy phthalate, 2-acryloyloxyethyl succinate, and 2-acryloyloxyethyl hexahydrophthalate.

Light-transmissive film 14 may further include an isocyanurate compound as a main component.

An isocyanurate compound is a compound having all isocyanurate skeleton and an alkoxysilyl group. As light-transmissive film 14, a material including, as main components, a methacrylic ester, a (meth)acrylic ester, a fluorine-containing monomer, a carboxy-containing monomer, and a well-known isocyanurate compound may be employed.

### [Test Result]

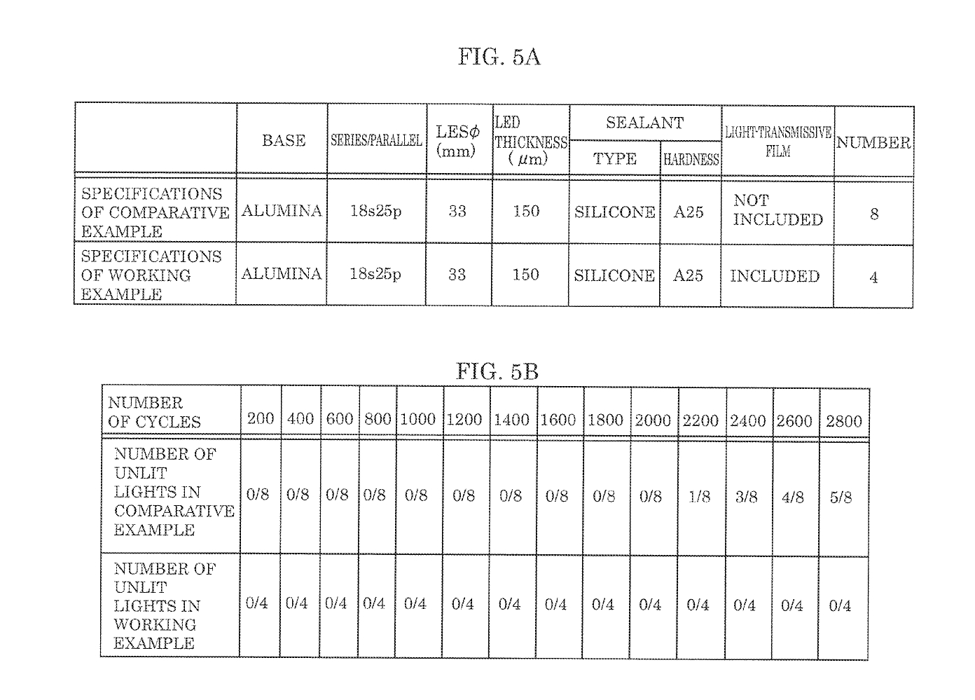

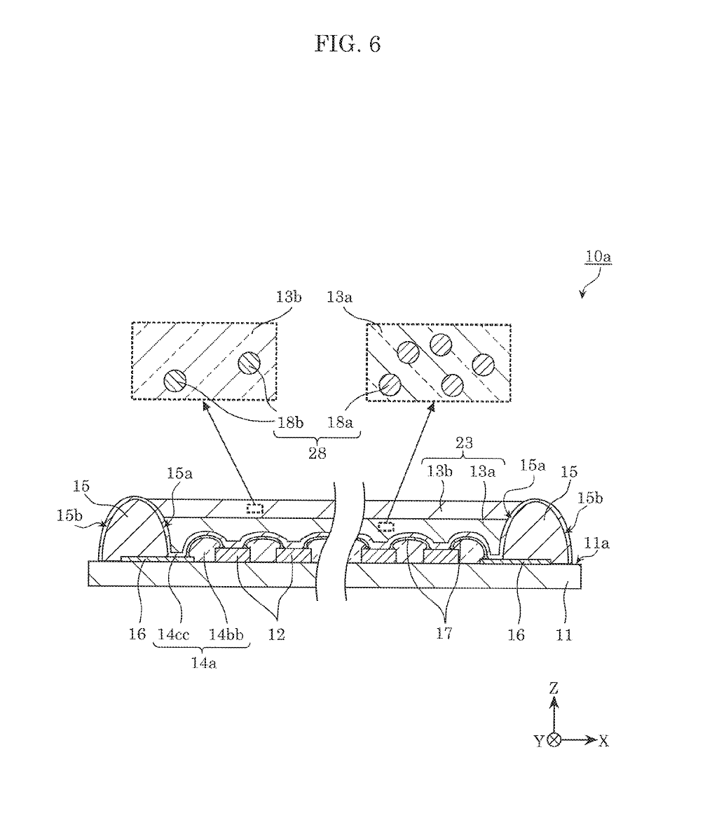

Next, with reference to FIGS. 5A and 5B, the result of a heat cycle test of light-emitting apparatus 10 will be described.

FIG. 5A is a table for illustrating a configuration of a light-emitting apparatus according to a working example (more specifically, one example of light-emitting apparatus 10) and a configuration of a light-emitting apparatus according to a comparative example. Specifically, FIG. 5A is a table of materials, dimensions, etc. employed for the light-emitting apparatus according to the working example and the light-emitting apparatus according to the comparative example.

Alumina is used as a material of base 11 of the light-emitting apparatus according to the working example. On major surface 11a of base 11, 450 light-emitting elements (LED chips) 12 are mounted in total, in which 18 light-emitting elements are arranged in series and 25 light-emitting elements are arranged in parallel. The diameter of light emitting surface of the light-emitting apparatus according to the working example is 33 mm, and each LED chip 12 has a thickness of 150 μm. Sealant 13 (specifically, transparent resin material) of the light-emitting apparatus according to the working example is silicone resin, and sealant 13 has a hardness (type A durometer hardness) of 25. Moreover, the light-emitting apparatus according to the working example includes light-transmissive film 14.

Alumina is used as a material of base 11 of the light-emitting apparatus according to the comparative example. On major surface 11a of base 11, 450 light-emitting elements (LED chips) 12 are mounted in total, in which 18 light-emitting elements are arranged in series and 25 light-emitting elements are arranged in parallel. The diameter of light emitting surface of the light-emitting apparatus according to the comparative example is 33 mm, and the thickness of each LED chip 12 is 150 μm. Sealant 13 (specifically, transparent resin material) of the light-emitting apparatus according to the comparative example is silicone resin, and sealant 13 has a hardness (type A durometer hardness) of 25.

Here, the light-emitting apparatus according to the comparative example does not include light-transmissive film 14. In other words, the light-emitting apparatus according to the comparative example only differs from the light-emitting apparatus according to the working example in that there is no light-transmissive film 14.

Note that frame 15 of the light-emitting apparatus according to the working example and frame 15 of the light-emitting apparatus according to the comparative example have a thickness (i.e., the height from the major surface of the substrate) of approximately 600 μm, and each of the metal wires have a diameter of approximately 20 μm.

FIG. 5B is a table showing the result of the heat cycle test performed on the light-emitting apparatus according to the working example and the light-emitting apparatus according to the comparative example. Note that four light-emitting apparatuses according to the working example and eight light-emitting apparatuses according to the comparative example were tested. As the heat cycle test, the light-emitting apparatuses were subjected to the temperature of −40 degrees Celsius for 30 minutes and then subjected to the temperature of +105 degrees Celsius for 30 minutes in a cycle. The test result shown in FIG. 5B indicate the number of failures after a plurality of cycles were performed. The failure here means that light-emitting apparatuses are unlit.

As shown in FIG. 5B, no failure was occurred up to 2000 cycles in the light-emitting apparatuses according to the working example or the light-emitting apparatuses according to the comparative example. After 2200 cycles were performed, the number of failures occurred in the light-emitting apparatuses according to the working example was zero, and the number of failures occurred in the light-emitting apparatuses according to the comparative example was one. After 2400 cycles were performed, the number of failures occurred in the light-emitting apparatuses according to the working example was zero, and the number of failures occurred in the light-emitting apparatuses according to the comparative example was three. After 2600 cycles were performed, the number of failures occurred in the light-emitting apparatuses according to the working example was zero, and the number of failures occurred in the light-emitting apparatuses according to the comparative example was four. After 2800 cycles were performed, the number of failures occurred in the light-emitting apparatuses according to the working example was zero, and the number of failures occurred in the light-emitting apparatuses according to the comparative example was five.

In view of the above result, heat cycle resistance significantly increases when light-emitting apparatus 10 includes light-transmissive film 14.

### [Effects, etc.]

As described above, light-emitting apparatus 10 includes: base 11; wiring pattern 16 disposed on major surface 11a of base 11; light-emitting element 12 mounted on major surface 11a of base 11; metal wire 17 that electrically connects light-emitting element 12 and wiring pattern 16; light-transmissive film 14 that covers metal wire 17, at least a portion of wiring pattern 16, and at least a portion of light-emitting element 12; and sealant 13 that covers light-transmissive film 14. Light-transmissive film 14 includes, wall portion 14b that is located between metal wire 17 and base 11, and that extends from major surface 11a of base 11 to metal wire 17.

With such a configuration, wall portion 14b included in light-transmissive film 14 supports metal wire 17 from below. Accordingly, metal wire 17 is supported by wall portion 14b of light-transmissive film 14, and thus less likely to deform due to the expansion and contraction of sealant 13. This reduces breakage of metal wire 17 due to the thermal expansion and contraction of sealant 13, and thus the heat cycle resistance of light-emitting apparatus 10 improves.

For example, light-emitting apparatus 10 includes frame 15 that surrounds light-emitting element 12 in a top view of major surface 11a of base 11.

Light-transmissive film 14 is formed, for example, using a solution in which the material of light-transmissive film 14 is diluted with a liquid diluent, which is a solvent. Thus, light-transmissive film 14 may be simply and conveniently formed when light-emitting apparatus 10 includes frame 15. Moreover, by employing a material having a high light reflectance as frame 15, for example, the light emitted by light-emitting element 12 is easily reflected off frame 15. As a result, the light extraction efficiency of light-emitting apparatus 10 improves.

Light-transmissive film 14 covers a portion of frame 15, for example. In this case, thickness t1 of light-transmissive film 14, which is a thickness of light-transmissive film 14 in a portion that covers light-emitting element 12, is greater than thickness t2 of light-transmissive film 14, which is a thickness of light-transmissive film 14 in a portion that covers frame 15.

By covering also inner surface 15a of frame 15, metal wires 17 are unlikely to deform due to the expansion and contraction of sealant 13. However, for example, there is a contact point between metal wire 17 and light-emitting element 12 on the upper surface of light-emitting element 12 where metal wire 17 is bonded to light-emitting element 12. The contacts point is more likely to be strongly affected by heat cycling. In other words, the contact point is more likely to affect the breakage of metal wire 17. Thus, by increasing the thickness of light-transmissive film 14 in a portion where the contact point is (i.e., thickness t1 of light-transmissive film 14 on the upper surface side of light-emitting element 12), the heat cycle resistance further improves. Therefore, the heat cycle resistance can be further improved with fewer materials by having a configuration in which thickness t1 of light-transmissive film 14, which is a thickness of light-transmissive film 14 in a portion that covers light-emitting element 12, is greater than thickness t2 of light-transmissive film 14, which is a thickness of light-transmissive film 14 in a portion that covers frame 15.

Moreover, thickness t3 of light-transmissive film 14 in a portion that covers metal wire 17 is at most 50 μm, for example.

Increasing thickness t3 of light-transmissive film 14 improves the heat cycle resistance. However, when thickness t3 is too thick, the light extraction efficiency of light emitted from light-emitting element 12 of light-emitting apparatus 10 may decrease. Accordingly, with thickness t3 of light-transmissive film 14 of at most 50 μm, the heat cycle resistance of light-emitting apparatus 10 can be improved, while the decrease in the light extraction efficiency is reduced.

Moreover, the hardness of light-transmissive film 14 may be greater than the hardness of sealant 13, for example. In other words, a material that is more unlikely to expand with heat than sealant 13 may be employed as light-transmissive film 14.

With this, metal wire 17 is covered with light-transmissive film 14 that is greater in hardness (i.e., unlikely to expand with heat) than sealant 13, metal wire 17 is more unlikely to be affected by heat cycling. Thus, with such a configuration, the heat cycle resistance of light-emitting apparatus 10 is further improved.

Moreover, for example, sealant 13 includes at least 10 ppm of cerium (Ce).

When a silicone resin is employed as sealant 13, the silicone resin bonds with oxygen in the atmosphere and hardens, and the elastic modulus of the silicone resin may increase. At this time, the stress to be applied to metal wire 17 from sealant 13 due to heat cycling increases, and thus metal wire 17 is more likely to break. When sealant 13 includes at least 10 ppm of Ce, hardening of sealant 13 due to its bonding with oxygen can be reduced. Thus, with such a configuration, the heat cycle resistance of light-emitting apparatus 10 further improves.

Moreover, light-emitting apparatus 10 further includes phosphor 18 that is sealed by sealant 13 and emits fluorescence, and light emitted by light-emitting element 12 includes excitation light for phosphor 18, for example.

With this, even when a material that emits a single color is employed, for example, blue LED chip that emits blue light is employed as light-emitting element 12, white light having improved color rendering properties can be emitted from light-emitting apparatus 10 by appropriately selecting phosphor 18.

For example, light-emitting apparatus 10 further includes inorganic filler 20 sealed by sealant 18.

With this, when sealant 13 includes phosphor 18, settling of phosphor 18 can be reduced.

For example, light-transmissive film 14 include, as a main component, one of (i) a homopolymer of SiH group-containing (meth)acrylic ester and (ii) a copolymer of SiH group-containing (meth)acrylic ester and at least one selected from the group consisting of acrylic esters and methacrylic esters.

Employing such a material as light-transmissive film 14 can improve the adhesiveness between light-transmissive film 14 and sealant 13, and retard the corrosion of metal wire 17.

For example, light-transmissive film 14 may include, as a main component, an acrylic resin including at least one of (i) an acrylic ester containing an Si-vinyl group and not containing an SiH group and (ii) a methacrylic ester containing an Si-vinyl group and not containing an SiH group.

Employing such a material as light-transmissive film 14 can also improve the adhesiveness between light-transmissive film 14 and sealant 13, and retard corrosion of metal wire 17.

For example, light-transmissive film 14 may include, as a main component, a reaction product of a (poly)silazane-based compound. For example, the (poly)silazane-based compound generates hydrogen and ammonia when producing the reaction product. The reaction product is, for example, SiO₂.

Employing such a material as light-transmissive film 14 can also improve the adhesiveness between light-transmissive film 14 and sealant 13, and retard corrosion of metal wire 17.

Light-transmissive film 14 may include, as a main component, an acrylic resin including at least one of (i) a (poly)silazane-based compound and an SiH group-containing acrylic ester and (ii) an SiH group-containing methacrylic ester.

Employing such a material as light-transmissive film 14 reduces breaking of light-transmissive film 14 and sealant 13 due to heat cycling.

For example, light-transmissive film 14 includes, as main components, a methacrylic ester, an (meth)acrylic ester, and a fluorine-containing monomer.

Employing such a material as light-transmissive film 14 retards corrosion such as sulfuration of metal wire 17 covered with light-transmissive film 14.

For example, light-transmissive film 14 may further include a carboxy containing monomer as a main component.

Further employing such a material as light-transmissive film 14 retards corrosion such as sulfuration of metal wire 17 covered with light-transmissive film 14, and also reduces breaking of light-transmissive film 14 and sealant 13 due to heat cycling.

For example, light-transmissive film 14 may further include an isocyanurate compound as a main component.

Further employing such a material as light-transmissive film 14 further retards corrosion such as sulfuration of metal wire 17 covered with light-transmissive film 14, and also reduces breaking of light-transmissive film 14 and sealant 13 due to heat cycling.

### Embodiment 2

In light-emitting apparatus 10 according to Embodiment 1, sealant 13 includes one layer. In light-emitting apparatus 10a according to Embodiment 2, sealant 13 includes two layers.

The following describes a light-emitting apparatus according to Embodiment 2 with reference to FIG. 6. Note that in the descriptions of the light-emitting apparatus according to Embodiment 2, configurations that are essentially the same as the configurations of light-emitting apparatus 10 according to Embodiment 1 share like reference signs. Accordingly, duplicate description may be omitted or simplified.

### [Configuration]

FIG. 6 is a cross-sectional view of light-emitting apparatus 10a according to Embodiment 2. Note that the cross-sectional view illustrated in FIG. 6 is a cross-section of light-emitting apparatus 10a corresponding to the cross-sectional view illustrated in FIG. 2.

As illustrated in FIG. 6, light-emitting apparatus 10a according to Embodiment 2 includes: base 11, a plurality of light-emitting elements 12, sealant 23, light-transmissive film 14a, frame 15, wiring patterns 16, and metal wires 17. Although not illustrated, wiring patterns 16 are electrically connected to electrodes 16a and 16b. Electrodes 16a and 16b are not covered with sealant 13, similar to light-emitting apparatus 10 illustrated in FIG. 1. Electrodes 16a and 16b are connected to an external commercial power source, etc., which is not illustrated. Light-emitting apparatus 10a emits light with electric power supplied from the external commercial power source, etc.

Light-transmissive film 14a is a light-transmissive resin material and covers each of metal wires 17, similar to light-transmissive film 14. Light-transmissive film 14a covers, for example, the entire perimeter in the radial direction of metal wire 17. Light-transmissive film 14a includes wall portion 14bb that is located between metal wire 17 and base 11 and that extends from major surface 11a of base 11 to metal wire 17. Light-transmissive film 14a also includes layer portion 14cc that is a layer covering at least a portion of wiring pattern 16 and at least a portion of light-emitting element 12. Moreover, wall portion 14bb of light-transmissive film 14a is formed continuously to cover metal wire 17 along the extending direction of metal wire 17, in a top view of major surface 11a of base 11. Moreover, light-transmissive film 14a continuously covers metal wire 17, major surface 11a of base 11, wiring pattern 16, and light-emitting element 12.

Similar to wall portion 14b included in light-transmissive film 14 according to Embodiment 1, wall portion 14bb is formed to extend from major surface of base 11 to metal wire 17, and support metal wire 17 from below. Wall portion 14bb is formed continuously along wiring pattern 16 and light-emitting element 12, for example. At least a portion of wall portion 14bb is located at a position surrounded by major surface 11a of base 11, light-emitting element 12, wiring pattern 16, and metal wire 17 that electrically connects light-emitting element 12 and wiring pattern 16. For example, when light-emitting apparatus 10a includes two light-emitting elements 12, at least a portion of wall portion 14bb is located at a position surrounded by major surface 11a of base 11, two light-emitting elements 12, and metal wire 17 that electrically connects the two light-emitting elements 12. For example, the width of wall portion 14bb in the direction orthogonal to the extending direction of metal wire 17 (i.e. the width in the Y axis direction) is partially thinner than the diameter of metal wire 17. The extending direction of metal wire 17 is the direction parallel to surface 11a.

Unlike light-transmissive film 14 according to Embodiment 1, coverage by light-transmissive film 14a according to Embodiment 2 continuously extends to outer surface 15b of frame 15 in a cross-sectional view orthogonal to major surface 11a of base 11. Outer surface 15b of frame 15 is a surface that is opposite inner surface 15a that faces light-emitting element 12. Specifically, coverage by layer portion 14cc of light-transmissive film 14a continuously extends from major surface 11a of base 11, wiring pattern 16, etc. to inner surface 15a of frame 15, and further continuously extends from inner surface 15a to outer surface 15b.

Note that light-transmissive film 14 and light-transmissive film 14a may be formed using the same material.

Sealant 23 is a sealing member that seals a plurality of light-emitting elements 12, light-transmissive film 14a, metal wires 17, and portions of wiring patterns 16. In the plan view, sealant 23 is formed in a circular shape by being dammed up by frame 15 having an circular ring shape, similar to sealant 13 included in light-emitting apparatus 10 according to Embodiment 1.

Sealant 23 according to Embodiment 2 includes first sealant layer 13a that covers light-emitting element 12, and second sealant layer 13b that covers first sealant layer 13a. Here, the density of phosphor 28 sealed by first sealant layer 13a is set to be higher than the density of phosphor 28 sealed by second sealant layer 13b. For example, the density of phosphor 28 in sealant 23 can be changed by spending a longer time curing sealant 13 and intentionally allowing phosphor 28 to settle.

Note that materials to be used for first sealant layer 13a and second sealant layer 13b of sealant 23 may be different or the same. When the same material is used, no interface is formed between first sealant layer 13a and second sealant layer 13b illustrated in FIG. 6. As sealant 23, a silicone resin is used, for example. However, sealant 23 may be an epoxy resin or a urea resin, for example.

Phosphor 28 sealed by first sealant layer 13a and phosphor 28 sealed by second sealant layer 13b may be the same or different from each other. FIG. 6 illustrates an example in which phosphor 28 includes first phosphor 18a sealed by first sealant layer 13a, and second phosphor 18b that is sealed by second sealant layer 13b and emits fluorescence having a spectrum different from a spectrum of fluorescence emitted by first phosphor 18a. The light emitted by light-emitting element 12 includes excitation light for second phosphor 18b.

As first phosphor 18a, for example, (Sr,Ca)AlSiN₃:Eu²⁺ phosphor having a spectrum whose center wavelength is at least 610 nm and at most 620 nm may be employed, which is one example of a red phosphor. As second phosphor 18b, for example, Lu₃Al₅O₁₂: Ce³⁺ phosphor having a spectrum whose center wavelength is at least 540 nm and at most 550 nm may be employed, which is one example of a green phosphor. Of course, a green phosphor may be employed as first phosphor 18a, and a red phosphor may be employed as second phosphor 18b.

### [Effects, etc.]

As described above, in a cross-sectional view orthogonal to major surface 11a of base 11, coverage by light-transmissive film 14a included in light-emitting apparatus 10a according to Embodiment 2 continuously extends to outer surface 15b of frame 15. Outer surface 15b of frame 15 is a surface that is opposite inner surface 15a that faces light-emitting element 12.

Such a configuration further improves the heat cycle resistance.

For example, sealant 23 includes first sealant layer 13a that covers light-emitting element 12, and second sealant layer 13b that covers first sealant layer 13a. In this case, the density of phosphor 28 sealed by first sealant layer 13a may be higher than the density of phosphor 28 sealed by second sealant layer 13b.

This makes first sealant layer 13a more unlikely to expand (deform) with heat, compared with second sealant layer 13b. Thus, metal wire 17 is more unlikely to break in such a configuration.

For example, phosphor 28 includes: first phosphor 18a sealed by first sealant layer 13a; and second phosphor 18b that is sealed by second sealant layer 13b and emits fluorescence having a spectrum different from a spectrum of fluorescence emitted by first phosphor 18a. The light emitted by light-emitting element 12 includes excitation light for second phosphor 18b.

Accordingly, light-emitting apparatus 10a includes a plurality of phosphors that emit mutually different fluorescence. This allows light-emitting apparatus 10a to emit various colors of light by mixing the light. Thus, such a configuration allows light-emitting apparatus 10a to emit light having improved color rendering properties.

### Other Embodiments

Hereinbefore, the light emitting apparatuses according to Embodiment 1 and Embodiment 2 have been described, but the present disclosure is not limited to the above embodiments.

In the above embodiments, the light-emitting apparatus emits white light using a combination of LED chips, which are one example of light-emitting elements that emit blue light, and yellow phosphor particles. However, the configuration for emitting white light is not limited to this.

For example, an LED chip that emits blue light may be combined with red phosphor particles and green phosphor particles. An ultraviolet LED chip that emits ultraviolet light having a shorter wavelength than the wavelength of an LED chip that emits blue light may be combined with blue phosphor particles, green phosphor particles, and red phosphor particles that respectively emit blue light, red light, and green light by being excited mainly by ultraviolet light.

Moreover, in the above embodiments, an LED chip mounted on the substrate is connected with another LED chip in a chip-to-chip configuration by a bonding wire. However, an LED chip may be connected, by a metal wire, with a wiring pattern provided on the substrate, and electrically connected with another LED chip via the wiring pattern.

Moreover, in the above embodiments, an LED chip is illustrated as an example of the light-emitting element included in the light-emitting apparatus. However, a semiconductor light-emitting element such as a semiconductor laser or a solid-state light-emitting element such as an organic electroluminescent (EL) element or an inorganic EL element may be employed as the light-emitting element.

Moreover, the light-emitting apparatus may include two or more types of the light-emitting elements haying different emission colors. For example, in addition to the LED chip that emits blue light, the light-emitting apparatus may include an LED chip that emits red light, for the purposes of enhancing color rendering properties.

In other instances, various modifications to the embodiments according to the present disclosure described above that may be conceived by those skilled in the art and embodiments implemented by any combination of the structural components and functions shown in the embodiments are also included within the scope of the present disclosure, without departing from the essence of the present disclosure.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A light-emitting apparatus, comprising:
a base;
a wiring pattern disposed on a major surface of the base;
a light-emitting element mounted on the major surface of the base;
a metal wire that electrically connects the light-emitting element and the wiring pattern;
a light-transmissive film that covers the metal wire, at least a portion of the wiring pattern, and at least a portion of the light-emitting element; and
a sealant that covers the light-transmissive film, wherein
the light-transmissive film includes a wall portion that is located between the metal wire and the base, and that extends from the major surface of the base to the metal wire.

2. The light-emitting apparatus according to claim 1, further comprising:
a frame that surrounds the light-emitting element in a top view of the major surface.

3. The light-emitting apparatus according to claim 2, wherein
the light-transmissive film covers a portion of the frame, and
a thickness of the light-transmissive film in a portion that covers the light-emitting element is greater than a thickness of the light-transmissive film in the portion that covers the frame.

4. The light-emitting apparatus according to claim 3, wherein
in a cross-sectional view orthogonal to the major surface, coverage by the light-transmissive film continuously extends to an outer surface of the frame, the outer surface being a surface that is opposite an inner surface that faces the light-emitting element.

6. The light-emitting apparatus according to claim 1, wherein
a thickness of the light-transmissive film in a portion that covers the metal wire is at most 50 μm.

6. The light-emitting apparatus according to claim 1, wherein
a hardness of the light-transmissive film is greater than a hardness of the sealant.

7. The light-emitting apparatus according to claim 1, wherein
the sealant includes at least 10 ppm of Ce.

8. The light-emitting apparatus according to claim 1, further comprising:
a phosphor that is sealed by the sealant and emits fluorescence, wherein
light emitted by the light-emitting element comprises excitation light for the phosphor.

9. The light-emitting apparatus according to claim 1, further comprising:
an inorganic filler sealed by the sealant.

10. The light-emitting apparatus according to claim 8, wherein
the sealant includes a first, sealant layer that covers the light-emitting element, and a second sealant layer that covers the first sealant layer, and
a density of the phosphor sealed by the first sealant layer is higher than a density of the phosphor sealed by the second sealant layer.

11. The light-emitting apparatus according to claim 10, wherein
the phosphor includes:
a first phosphor sealed by the first sealant layer; and
a second phosphor that is sealed by the second sealant layer and emits fluorescence having a spectrum different from a spectrum of fluorescence emitted by the first phosphor, wherein
the light emitted by the light-emitting element comprises excitation light for the second phosphor.

12. The light-emitting apparatus according to claim 1, wherein
the light-transmissive film includes, as a main component,
one of (i) a homopolymer of SiH group-containing (meth)acrylic ester and
(ii) a copolymer of SiH group-containing (meth)acrylic ester and at least one selected from the group consisting of acrylic esters and methacrylic esters.

13. The light-emitting apparatus according to claim 1, wherein
the light-transmissive film includes, as a main component,
an acrylic resin including at least one of (i) an acrylic ester containing an Si-vinyl group and not containing an SiH group and (ii) a methacrylic ester containing an Si-vinyl group and not containing an SiH group.

14. The light-emitting apparatus according to claim 1, wherein
the light-transmissive film includes, as a main component,
a reaction product of a (poly)silazane-based compound.

15. The light-emitting apparatus according to claim 14, wherein
the (poly)silazane-based compound generates hydrogen and ammonia when producing the reaction product.

16. The light-emitting apparatus according o claim 14, wherein
the reaction product includes SiO₂.

17. The light-emitting apparatus according to claim 1, wherein
the light-transmissive film includes, as a main component,
an acrylic resin including at least one of (i) a (poly)silazane-based compound and an SiH group-containing acrylic ester and (ii) an SiH group-containing methacrylic ester.

18. The light-emitting apparatus according to claim 1, wherein
the light-transmissive film includes, as main components, a methacrylic ester, an (meth)acrylic ester, and a fluorine-containing monomer.

19. The light-emitting apparatus according to claim 18, wherein
the light-transmissive film further includes a carboxy-containing monomer as a main component.

20. The light-emitting apparatus according to claim 19, wherein
the light-transmissive film further includes an isocyanurate compound as a main component.
